(19) United States
(12) Patent Application Publication
(10) Pub. No.: US 2015/0008524 A1
(43) Pub. Date: Jan. 8, 2015

(54) Integrated circuit device structure and fabrication method thereof

(71) Applicant: UNITED MICROELECTRONICS CORP., Hsin-Chu City (TW)

(72) Inventors: Ching-Wen Hung, Tainan City (TW); Chih-Sen Huang, Tainan City (TW)

(21) Appl. No.: 13/933,141

(22) Filed: Jul. 2, 2013

(51) Int. Cl. H01L 27/088; H01L 29/66

(52) U.S. Cl. CPC H01L 27/088; H01L 29/66477
USPC 257/368; 438/197

(57) ABSTRACT

An integrated circuit device structure, in which, a diffusion region is formed in a substrate, an extension conductor structure is contacted with the diffusion region and extended externally to a position along a surface of the substrate, the position is outside the diffusion region, another extension conductor structure is contacted with the diffusion region, a jumper conductor structure is disposed over the substrate and on these two extension conductor structures for electrically connecting these two extension conductor structures, the jumper conductor structure may be over one or more gate structures, a contact structure penetrates through a dielectric layer to be contacted with the jumper conductor structure, and a metal conductor line is contacted with the contact structure.

### BACKGROUND OF THE INVENTION

1. Field of the Invention

The present invention relates to a semiconductor technology, and particularly to an integrated circuit device structure and fabrication method thereof.

2. Description of the Prior Art

It is well-known that, in semiconductor industry, memory devices include memory cells and logic circuits. NOR and NAND are basic functional units of many CMOS logic circuits. When an electric circuit is implemented to become a layout, metal inter-connect is usually employed to electrically connect components or elements. For example, the first layer metal layer (Metal-1) is conventionally utilized to electrically connect the contact structures disposed on common drain/source regions. However, in order to preserve a space above the drain/source region for forming a metal inter-connect, a metal conductor line is usually formed utilizing Metal-1 on the contact structure disposed on the drain/source and extended externally beyond the range of the diffusion region and connected with another metal interconnect formed of Metal-1, to accomplish a desired electric connection. Accordingly, area should be increased for disposing the metal conductor line. Therefore, there is still a need for a novel integrated circuit device structure or fabrication method thereof for reducing layout area.

### SUMMARY OF THE INVENTION

An objective of the present invention is to provide a novel integrated circuit device structure, and accordingly layout area may be reduced.

According to an embodiment, an integrated circuit device structure includes a substrate, a first diffusion region, a first gate structure, a first extension conductor structure, a second extension conductor structure, a jumper conductor structure, a dielectric layer, a first contact structure and a first metal conductor line. The first diffusion region is formed in the substrate. The first gate structure is formed over the substrate and across the first diffusion region. The first extension conductor structure is formed over the substrate and contacted with the first diffusion region. The first extension conductor structure is extended along a surface of the substrate to a position. The position is outside the diffusion region. A second extension conductor structure is formed over the substrate. The jumper conductor structure is disposed over the substrate. The jumper conductor structure is on the first extension conductor structure and on the second extension conductor structure to electrically connect the first extension conductor structure and the second extension conductor structure. The dielectric layer is formed over the substrate, the first gate structure, the first extension conductor structure, the second extension conductor structure and the jumper conductor structure. The first contact structure penetrates the dielectric layer to be contacted with the jumper conductor structure. The first metal conductor line is formed on the dielectric layer and contacted with the first contact structure.

According to another embodiment of the present invention, a method of fabricating an integrated circuit device structure includes steps as follows. A substrate is provided. A first diffusion region is formed in the substrate. A first gate structure is formed over the substrate and across the first diffusion region. A first extension conductor structure and a second extension conductor structure are formed over the substrate and contacted with the first diffusion region. The first extension conductor structure is extended to a position along a surface of the substrate and the position is outside the diffusion region. A first dielectric layer is formed over the substrate, the first gate structure, the first extension conductor structure, and the second extension conductor structure. A jumper conductor structure is formed in the first dielectric layer and on the first extension conductor structure and on the second extension conductor structure to electrically connect the first extension conductor structure and the second extension conductor structure. A second dielectric layer is formed over the jumper conductor structure. A first contact structure is formed to penetrate the second dielectric layer so as to be contacted with the jumper conductor structure. A first metal conductor line is formed on or in the second dielectric layer. The first metal conductor line is contacted with the first contact structure.

In the embodiments of the present invention, an extension conductor structure on a diffusion region is allowed to be extended along surface of the substrate to a position outside the diffusion region, and a jumper conductor structure is formed on this extension conductor structure and on another extension conductor structure and over the substrate to electrically connect these two extension conductor structures. The jumper conductor structures may be accomplished utilizing Metal-0 material instead of utilizing Metal-1 material requiring a turning line arrangement for electric connection. The jumper conductor structure maybe disposed within the whole unit range, and the space above the diffusion region can be utilized by Metal-1 inter-connection. Accordingly, the layout area can be reduced without increasing the height of a unit as a whole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic plan view illustrating an integrated circuit device structure according to an embodiment of the present invention;

FIG. 2 is a schematic cross view illustrating one aspect of an integrated circuit device structure according to an embodiment of the present invention;

FIG. 3 is a schematic cross view illustrating another aspect of an integrated circuit device structure according to an embodiment of the present invention;

FIG. 4 is a schematic plan view illustrating an integrated circuit device structure according to another embodiment of the present invention;

FIG. 5 is a schematic plan view illustrating an integrated circuit device structure according to further another embodiment of the present invention;

FIG. 6 is a schematic plan view illustrating an integrated circuit device structure according to still another embodiment of the present invention;

FIG. 7 is schematic cross section view taken along the line XX′ shown in FIG. 6; and

FIG. 8 is schematic cross section view taken along the line YY′ shown in FIG. 6.

### DETAILED DESCRIPTION

Please refer to FIG. 1, which is a schematic plan view illustrating an integrated circuit device structure according to an embodiment of the present invention. The integrated circuit device structure includes a substrate 10, a diffusion region 12, a gate structure 14, an extension conductor structure, an extension conductor structure 18, a jumper conductor structure 20, a dielectric layer (not shown), a contact structure 22, and a metal conductor line 24. The substrate 10 may be for example a semiconductor substrate. The diffusion region 12 is a doped region formed in the substrate 10. The diffusion region 12 is generally surrounded by an isolation structure (not shown) having electrically isolation properties disposed in the substrate 10. The extension conductor structure 16 is formed over the substrate 10 and is contacted with the diffusion region 12. The extension conductor structure 16 is extended along surface of the substrate 10 to a position. The position is outside the substrate 10. The extension conductor structure 18 is formed over the substrate 10. The jumper conductor structure 20 is over the substrate 10 and on the extension conductor structure 16 and on the extension conductor structure 18 for electrically connecting the extension conductor structures 16 and 18. The dielectric layer (not shown) covers the substrate 10, the gate structure 14, the extension conductor structures 16 and 18 and the jumper conductor structure 20. The contact structure 22 penetrates the dielectric layer and is contacted with the jumper conductor structure 20. The metal conductor line 24 is formed on the surface of the dielectric layer and contacted with the contact structure 22, so that the metal conductor line 24 can be electrically connected to the common source or common drain of the diffusion 12 through the contact structure 22, the jumper conductor structure 20, and the extension conductor structures 16 and 18.

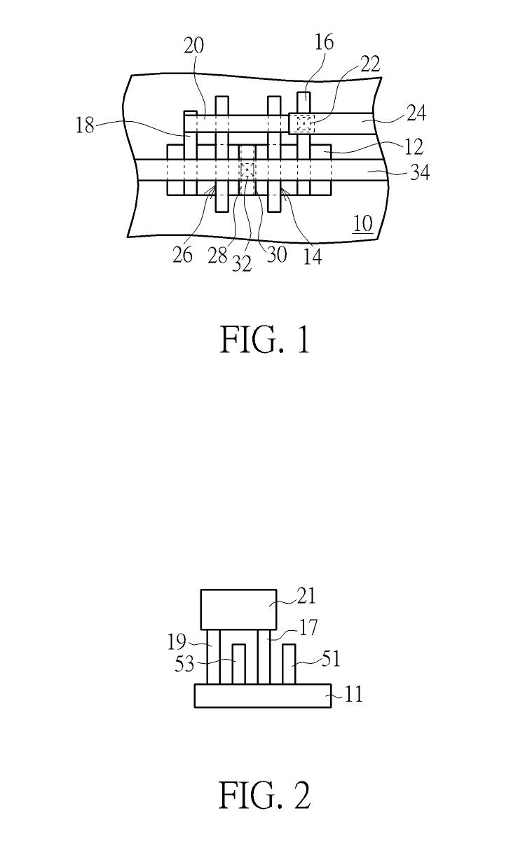

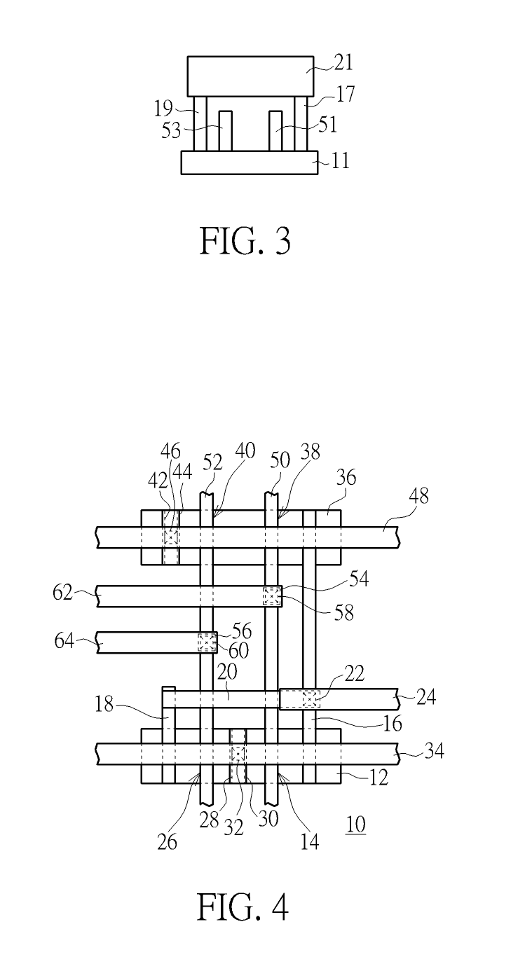

It is noted that, one of the features of the present invention is to form two extension conductor structures on two common source regions or two common drain regions correspondingly. One of the two extension conductor structures is extended to the outside of the drain/source region, i.e. the diffusion region, and the other one is not particularly restricted. The jumper conductor structure is allowed to connect these two extension conductor structures in a way of having two portions being disposed on these two extension conductor structures and over the substrate therebetween, so as to electrically connect these two extension conductor structures. Please refer to FIGS. 2 and 3, which are two schematic cross section views showing different embodiments of connection of the jumper conductor structure with two extension conductor structures. In which, the substrate 11 may include one or two of a diffusion region and an isolation structure. The gate lines 51 and 53 are disposed on the substrate 11. The extension conductor structures 17 and 19 are also disposed on the substrate 11 and on both sides of one of the gate lines 51 and 53 (for example shown by FIG. 2) or one external sides of the two gate lines 51 and 53 (for example shown by FIG. 3). The jumper conductor structure 21 “jumps” over the gate line 53 or the gate lines 51 and 53 disposed between the extension conductor structures 17 and 19 to electrically connect the extension conductor structures 17 and 19. In one situation, the extension conductor structures 17 and 19 are higher than the gate lines 51 and 53.

Herein, the term, the zero layer metal layer (Metal-0), is relative to the conventional term the first layer metal layer (Metal-1). Metal-0 is a metal layer formed in the dielectric layer formed before Metal-1 is formed (i.e. pre-metal dielectric, PMD). For example, the metal conductor line 24 as shown in FIG. 1 is a Metal-1 metal layer formed using Metal-1 material.

Please still refer to FIG. 1. The integrated circuit device structure may further include a gate structure 26 formed over the substrate 10 and across the diffusion region 12. For example, the gate structure 26 and the gate structure 14 are arranged parallel on the diffusion region 12 as shown in FIG. 1. Furthermore, the integrated circuit device structure may include a structure for electrically connecting the diffusion region 12 to another metal conductor line. For example, a conductor structure 28 is disposed on the diffusion region 12, a conductor structure 30 is disposed on the conductor structure 28, a contact structure 32 is disposed on the conductor structure 30, and a metal conductor line 34 is disposed so as to be contacted with the contact structure 32 and the metal conductor line 34 can be located above the diffusion region 12. The metal conductor line 34 may be disposed above the diffusion region 12, so that the layout area can be reduced, as compared with conventional technology. The metal conductor line 34 maybe allowed to be electrically connected to a V_{dd} power supply device and the metal conductor line 24 outputs charges. Or, in other aspect, the metal conductor line 34 may be allowed to be electrically connected to a Vₛₛ power supply device and the metal conductor line 24 outputs charges.

Still as one embodiment shown in FIG. 1, when the aforesaid gate structure 26 is disposed, the conductor structure 28 may be allowed to be disposed between the gate structure 14 and the gate structure 26. The metal conductor line 34 may be electrically connected to the diffusion region 12 between the gate structure 14 and the gate structure 26 through the contact structure 32, the conductor structure 30, and the conductor structure 28. The metal conductor line 34 is disposed above the gate structures 14 and 26 and the extension conductor structures 16 and 18, so that the metal conductor line 34 will not be contacted with these elements or components to result in a short circuit. The extension conductor structure 16 is allowed to be on the side of the gate structure 14 opposite to the conductor structure 28, i.e. the extension conductor structure 16 and the conductor structure 28 are on different sides of the gate structure 14 from each other. The extension conductor structure 18 is allowed to be on the side of the gate structure 26 opposite to the conductor structure 28, i.e. the extension conductor structure 18 and the conductor structure 28 are on different sides of the gate structure 26 from each other. The metal conductor line 24 may be electrically connected to the extension conductor structures 16 and 18, which are contacted with the diffusion region 12, through the contact structure 22, and the jumper conductor structure 20. However, the present invention should not be limited thereto.

Please refer to FIG. 4, the integrated circuit device structure according to another embodiment of the present invention may further include a diffusion region 36 formed in the substrate 10, a gate structure 38, a gate structure 40 and a conductor structure 42 formed on the diffusion region 36, a conductor structure 44 formed on the conductor structure 42, a contact structure 46 formed on the conductor structure 44, and the metal conductor line 48 formed on the contact structure 46.

In a further situation, each of the gate structure 38 and the gate structure 14 may include a portion of the gate line 50. In other words, the gate line 50 is formed over the substrate 10 and across the diffusion regions 12 and 36. The portion across the diffusion region 12 may be for forming the gate structure 14, and the portion across the diffusion region 36 may be for forming the gate structure 38. Furthermore, each of the gate structure 40 and the gate structure 26 may include a portion of the gate line 52. In other words, the gate line 52 is formed over the substrate 10 and across the diffusion regions 12 and 36. The portion across the diffusion region 12 may be for forming the gate structure 26, and the portion across the diffusion region 36 may be for forming the gate structure 40. Furthermore, the extension conductor structure 16 may be extended to the diffusion region 36, so as to electrically connect the diffusion region 12 and the diffusion region 36.

Still refer to FIG. 4 . The integrated circuit device structure may further include a conductor structure 54 and a conductor structure 56 formed on the gate line 50 and the gate line 52 respectively, a contact structure 58 and a contact structure 60 formed on the conductor structure 54 and the conductor structure 56 respectively, a metal conductor line 62 and a metal conductor line 64 formed to be contacted with the contact structure 58 and the contact structure 60 respectively.

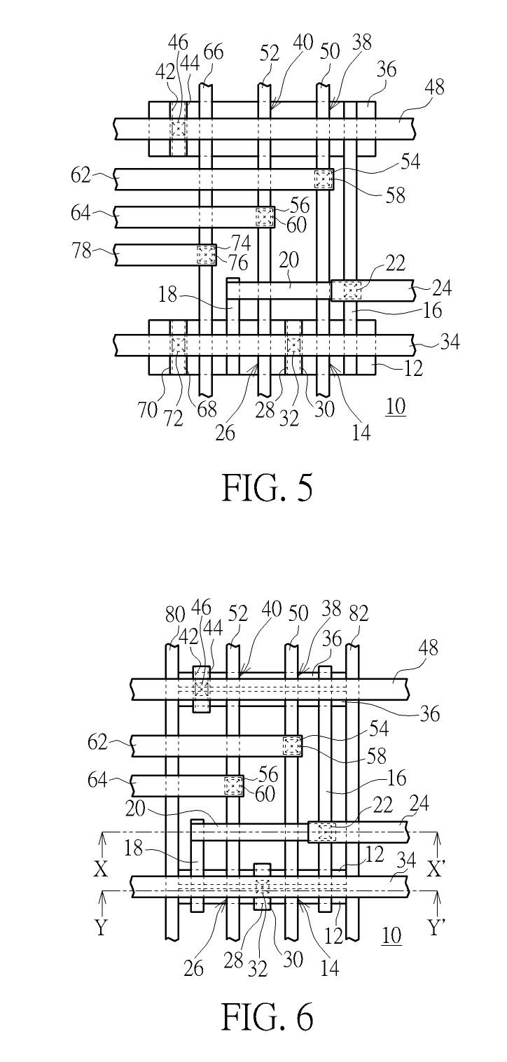

Please refer to FIG. 5. An integrated circuit device structure according to further another embodiment of the present invention may include more gates to increase more common drain/source regions. For example, the integrated circuit device structure may further include a gate line 66 formed across the diffusion region 12 and the diffusion region 36, a conductor structure 68 formed on the diffusion region 12, a conductor structure 70 formed on the conductor structure 68, and a contact structure 72 formed on the conductor structure 70. The metal conductor line 34 is contacted with the contact structure 72. Furthermore, the integrated circuit device structure may further include a conductor structure 74 formed on the gate line 66, a contact structure 76 formed on the conductor structure 74, and a metal conductor line 78 formed on the conductor structure 76.

Furthermore, the diffusion region of the integrated circuit device structure according to the present invention may be planar or have a fin shape. For example, when one or two of the diffusion regions 12 and 36 are fin-shaped, the integrated circuit device structure may further include two dummy gate lines for covering fin-shaped cross section at two ends of the diffusion regions 12 or 36 for protection. For example, as shown in FIG. 6, both of the diffusion regions 12 and 36 have a fin shape, in which, there may be more than one diffusion region 12 or 36. There are two diffusion regions 12 or 36, as shown in FIG. 6, for increasing surface area of diffusion region. Two dummy gate lines 80 and 82 cover the fin-shaped cross section of the two ends of the diffusion regions 12 and 36.

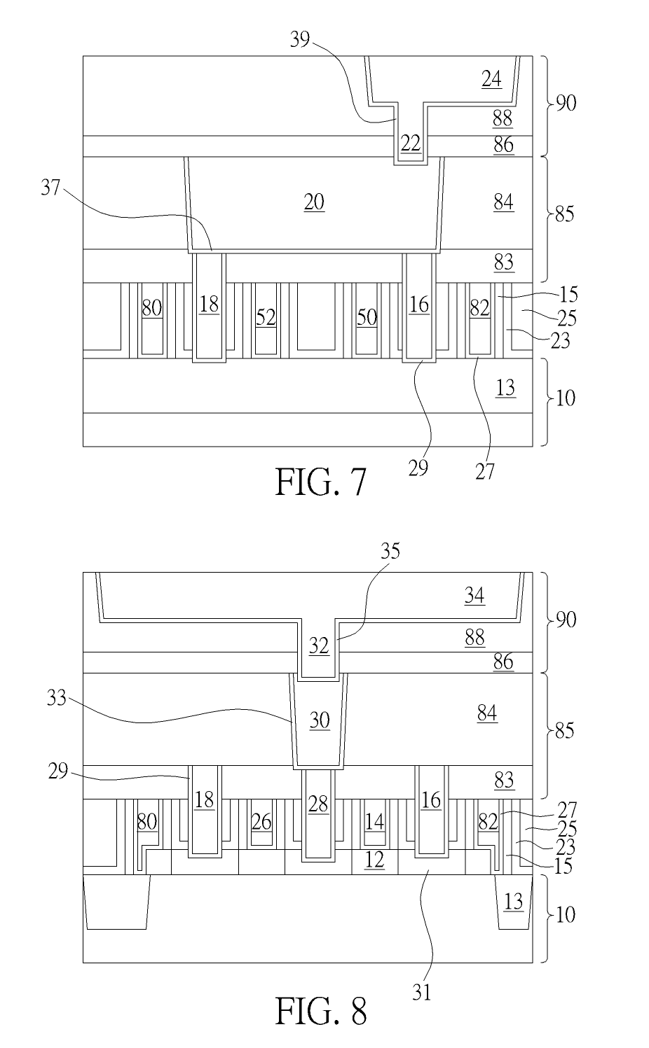

FIGS. 7 and 8 are schematic cross section views taken along the lines XX′ and YY′, respectively. Please referring to FIGS. 1, 7 and 8, according to another embodiment of the present invention, a method of fabricating an integrated circuit device structure includes steps as follows. First, a substrate 10 is provided. A diffusion region 12, for example the fin structure shown in FIG. 8, is formed in the substrate 10. The substrate 10 may further include a shallow trench isolation structure 13 surrounding the diffusion region 12. A gate structure 14 is formed over the substrate 10 and across the diffusion region 12. An extension conductor structure 16 and an extension conductor structure 18 are formed over the substrate 10 and contacted with the diffusion region 12. The extension conductor structure 16 is extended to a position along a surface of the substrate 10. The position is outside the diffusion region 12. A dielectric layer 84 is formed over the substrate 10, the gate structure 14, the extension conductor structure 16 and the extension conductor structure 18. A jumper conductor structure 20 is formed in the dielectric layer 84 and on the extension conductor structure 16 and on the extension conductor structure 18 to electrically connect the extension conductor structure 16 and the extension conductor structure 18. A dielectric layer 90 is formed over the jumper conductor structure 20. The dielectric layer 90 may include for example a multi-layered dielectric layer 86 and an inter-metal dielectric (IMD) 88. A contact structure 22 is formed to penetrate the dielectric layer 90 so as to be contacted with the jumper conductor structure 20. A metal conductor line 24 is formed on or in the dielectric layer 90. The metal conductor line 24 is contacted with the contact structure 22.

Still as shown in FIGS. 1 and 8, a gate structure 26 may be further formed over the substrate 10 and across the diffusion region 12. A conductor structure 28 may be further formed on the diffusion region 12. A conductor structure 30 may be formed on the conductor structure 28. A contact structure 32 may be formed on the conductor structure 30. A metal conductor line 34 maybe formed to be contacted with the contact structure 32 and located above the diffusion region 12. The conductor structure 28 may be allowed to be formed between the gate structure 14 and the gate structure 26. The extension conductor structure 16 and the conductor structure 28 are allowed to be formed on different sides of the gate structure 14 from each other. The extension conductor structure 18 and the conductor structure 28 are allowed to be formed on different sides of the gate structure 26 from each other.

In the aforesaid embodiments and others, referring to FIGS. 7 and 8, for example, each of the extension conductor structures 16 may include a slot contact having a slot shape and may include conductive material for example metal, such as tungsten, copper, or other suitable one. A barrier layer 29 may be further included for preventing metal atoms from migration into the substrate. The extension conductor structures 16 and 18 may be higher than the gate lines 50 and 52. For example, the former is 500 angstroms in height, and the latter is 300 angstroms in height. Such that the jumper conductor structure 20 disposed on the extension conductor structures 16 and 18 will not be contacted with the gate lines 50 and 52 to result in a short circuit. Each jumper conductor structure may include metal material and may be formed simultaneously with the formation of Metal-0 metal layer. The Metal-0 metal layer may use tungsten, copper, aluminum, or other suitable metal. A barrier layer 37 may be included for preventing metal atoms from migration. The metal conductor lines 24 and 34 may be formed as a conventional Metal-1 metal layer using for example tungsten, copper, aluminum, or other suitable metal. Barrier layers 39 and 35 may be included for preventing metal atoms from migration. The conductor structure 22 and 32 connected to the metal conductor lines 24 and 34 may be for example a via structure, and may be formed with the metal conductor lines 24 and 34 together through a dual damascene process. Each conductor structures 28 and 30 may include for example tungsten, copper, aluminum, or other suitable metal. A barrier layer 33 may be further included. The gate lines 50 and 52 or the gate structures 14 and 26 or the dummy gate lines 80 and 82 may include for example polysilicon or metal, for example tungsten (W), aluminum (Al), titanium (Ti), titanium nitride (TiN), titanium aluminide (TiAl3), tantalum (Ta), tantalum nitride (TaN), tantalum aluminum nitride (TaAlN), or any combination thereof. With respect to fin-shaped diffusion regions, the gate lines or the dummy gate lines may preferably include for example W, Al, Ti, TiN, TiAl3, Ta, TaN, TaAlN, or any combination thereof , and a barrier layer 27 may be further formed. With respect to planar diffusion regions, the gate lines or the dummy gate lines may preferably include for example Ta, Ti, TaN, TiN, or any combination thereof, and a high-k dielectric layer may be further formed. Spacers 15 may be further formed on sidewalls of gate lines 50 and 52 or gate structures 14 and 26 or dummy gate lines 80 and 82. A metal silicide layer 31 may be formed on the drain/source regions of the diffusion region in advance to improve the contact between the extension conductor structures 16 and 18 and the conductor structure 28 and the drain/source regions. A contact etch stop layer (CESL) 23 may be further formed on the metal silicide layer 31 and the spacers 15. The dielectric layers 25, 85 and 90 are employed to electrically isolate elements or components. The dielectric layer 85 may include a cap film 83 formed above gate structures and a pre-metal dielectric 84 formed before Metal-1 metal layer. The cap film 83 may protect gates and add height to the extension conductor structures 16 and 18. The dielectric layer 90 may include a multi-layered dielectric layer 86 and an inter-metal dielectric 88. Each dielectric layer may include conventional material and be formed by conventional processes.

The metal parts or components maybe formed using for example damascene or dual damascene process. The extension conductor structures or the conductor structures at the same level but arranged in different direction may be formed through two photolithography and etching processes separately to form trenches in different directions and thereafter the trenches may be filled with metal material, such as Metal-0 material, simultaneously.

The structure or fabrication method according to the present invention is applicable to standard NAND or NOR circuit having 2-, 3- or more inputs. When a NAND or NOR circuit having 4- or more inputs is desired, two or more jumper conductor structures maybe utilized, depending on layout design.

In the present invention, components or elements such as jumper conductor structures and the like are formed utilizing the zero layer metal layer (Metal-0) located within a pre-metal dielectric formed before the first layer metal layer (Metal-1), to share the layout loading utilizing Metal-1 conventionally, so that the layout can be flexible, and the layout area can be reduced without increasing the cell height. Furthermore, the jumper conductor structures and other conductor structures utilizing Metal-0 can be formed through forming trenches thereof by two-stages in accordance with arrangement directions respectively, so that exposure window in lithography processes can be improved and a well-ordered rectangular and orthogonal layout can be obtained.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit device structure, comprising:
a substrate;
a first diffusion region formed in the substrate;
a first gate structure formed over the substrate and spanning the first diffusion region;
a first extension conductor structure formed over the substrate and contacted with the first diffusion region, wherein the first extension conductor structure is extended to a position along a surface of the substrate, wherein the position is outside the diffusion region;
a second extension conductor structure formed over the substrate;
a jumper conductor structure disposed over the substrate and on the first extension conductor structure and on the second extension conductor structure to electrically connect the first extension conductor structure and the second extension conductor structure;
a dielectric layer formed over the substrate, the first gate structure, the first extension conductor structure, the second extension conductor structure and the jumper conductor structure;
a first contact structure penetrating the dielectric layer to be contacted with the jumper conductor structure; and
a first metal conductor line contacted with the first contact structure.

2. The integrated circuit device structure according to claim 1, wherein, the first extension conductor structure and the second extension conductor structure each comprise a slot contact structure.

3. The integrated circuit device structure according to claim 1, wherein, the jumper conductor structure comprises a metal layer.

4. The integrated circuit device structure according to claim 1, wherein, further comprises a second gate structure formed over the substrate and spanning the first diffusion region.

5. The integrated circuit device structure according to claim 1, further comprising:
a first conductor structure disposed on the first diffusion region;
a second conductor structure disposed on the first conductor structure;
a second contact structure disposed on the second conductor structure; and
a second metal conductor line contacted with the second contact structure and above the first diffusion region.

6. The integrated circuit device structure according to claim 5, further comprising:
a second gate structure disposed over the substrate and spanning the first diffusion region, wherein the first conductor structure is between the first gate structure and the second gate structure, the first extension conductor structure is at a side of the first gate structure opposite to the first conductor structure, and the second extension conductor structure is at a side of the second gate structure opposite to the first conductor structure.

7. The integrated circuit device structure according to claim 1, further comprising:
a second diffusion region formed in the substrate;
a third gate structure, a fourth gate structure and a third conductor structure disposed on the second diffusion region;
a fourth conductor structure disposed on the third conductor structure;
a third contact structure disposed on the fourth conductor structure; and
a third metal conductor line disposed on the third contact structure.

8. The integrated circuit device structure according to claim 7, wherein, the third gate structure and the first gate structure each comprise a portion of the first gate line, the fourth gate structure and the second gate structure each comprise a portion of the second gate line, and the first extension conductor structure is extended to the second diffusion region.

9. The integrated circuit device structure according to claim 1, wherein the first diffusion region is planar or has a shape of fin, and the integrated circuit device structure further comprises two dummy gate lines to cover two ends of the first diffusion region.

10. The integrated circuit device structure according to claim 7, wherein, the first diffusion region and the second diffusion region are planar or have a shape of fin, and the integrated circuit device structure further comprises two dummy gate lines to cover two ends of each of the first diffusion region and the second diffusion region.

11. A method of fabricating an integrated circuit device structure, comprising:
providing a substrate;
forming a first diffusion region in the substrate;
forming a first gate structure over the substrate and spanning the first diffusion region;
forming a first extension conductor structure and a second extension conductor structure over the substrate and contacted with the first diffusion region, wherein the first extension conductor structure is extended to a position along a surface of the substrate and the position is outside the diffusion region;
forming a first dielectric layer over the substrate, the first gate structure, the first extension conductor structure, and the second extension conductor structure;
forming a jumper conductor structure in the first dielectric layer and on the first extension conductor structure and on the second extension conductor structure to electrically connect the first extension conductor structure and the second extension conductor structure;
forming a second dielectric layer over the jumper conductor structure;
forming a first contact structure to penetrate the second dielectric layer to be contacted with the jumper conductor structure; and
forming a first metal conductor line allowing the first metal conductor line to be contacted with the first contact structure.

12. The method according to claim 11, wherein the first extension conductor structure and the second extension conductor structure each comprise a slot contact structure.

13. The method according to claim 11, wherein the jumper conductor structure comprises a metal layer.

14. The method according to claim 11, further comprising:
forming a second gate structure over the substrate and across the first diffusion region.

15. The method according to claim 11, further comprising:
forming a first conductor structure on the first diffusion region;
forming a second conductor structure on the first conductor structure;
forming a second contact structure on the second conductor structure; and
forming a second metal conductor line and allowing the second metal conductor line to be contacted the second contact structure and above the first diffusion region.

16. The method according to claim 15, further comprising:
forming a second gate structure over the substrate and across the first diffusion region, wherein the first conductor structure is between the first gate structure and the second gate structure, the first extension conductor structure is at a side of the first gate structure opposite to the first conductor structure, and the second extension conductor structure is at a side of the second gate structure opposite to the first conductor structure.

17. The method according to claim 11, further comprising:
forming a second diffusion region in the substrate;
forming a third gate structure, a fourth gate structure and a third conductor structure on the second diffusion region;
forming a fourth conductor structure on the third conductor structure;
forming a third contact structure on the fourth conductor structure; and
forming a third metal conductor line on the third contact structure.

18. The method according to claim 17, wherein, the third gate structure and the first gate structure each are allowed to comprise a portion of the first gate line, the fourth gate structure and the second gate structure each are allowed to comprise a portion of the second gate line, and the first extension conductor structure is allowed to be extended to the second diffusion region.

19. The method according to claim 11, wherein the first diffusion region is allowed to be planar or have a shape of fin, and the method further comprises:
forming two dummy gate lines covering two ends of the first diffusion region.

20. The method according to claim 17, wherein the first diffusion region and the second diffusion region are allowed to be planar or have a shape of fin, and the method further comprises:
forming two dummy gate lines covering two ends of each of the first diffusion region and the second diffusion region.
